(19) United States
(12) Patent Application Publication
(10) Pub. No.: US 2008/0242104 A1
(43) Pub. Date: Oct. 2, 2008

(54) SEMICONDUCTOR DEVICE, METHOD OF MANUFACTURING THEREOF AND MASK FOR DIVIDING EXPOSURE

(75) Inventors: Kazuhito HONMA, Kawasaki (JP); Masaru MIYAZAKI, Kawasaki (JP); Masanori ONODERA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUITSU LIMITED, Kawasaki-shi (JP)

(21) Appl. No.: 12/055,542

(22) Filed: Mar. 26, 2008

(30) Foreign Application Priority Data
Mar. 28, 2007 (JP) 2007-84440

(51) Int. Cl. H01L 21/302; G03F 1/00

(52) U.S. Cl. 438/746; 430/5; 257/E21.214

(57) ABSTRACT

A method of manufacturing a semiconductor device has a first exposure to the photoresist by using a first mask having a first portion of a monitor pattern, a second exposure to the photoresist by using a second mask having a second portion of the monitor pattern so that a first image of the first portion and a second image of the second portion are connected.

### CROSS-REFERENCE TO RELATED APPLICATIONS

This application is based upon and claims the benefit of priority from the prior Japanese Patent Application No. 2007-84440, filed on Mar. 28, 2007, the entire contents of which are incorporated herein by reference.

### BACKGROUND

The present invention relates to a semiconductor device, a manufacturing method thereof and a mask for dividing exposure.

In the manufacturing process of a semiconductor device such as a Large-Scale Integration (LSI), a resist pattern is formed by exposing a photoresist, and a device pattern having a desired form is formed by etching a film, using the resist pattern as a mask.

In the exposure process, there is a dividing exposure method exposing a chip region by connecting plural exposures, in addition to a bulk print method exposing a chip region of a semiconductor substrate at one exposure. In the dividing exposure method, there is an advantage that exposure can be performed even when the chip size is larger than the exposed region such as a display device.

FIG. 1 is a schematic view showing the dividing exposure method.

In a mask for dividing exposure 12, shielding patterns 11 are formed separately in a first and second sub-fields SF1, SF2 over a transparent substrate 10 in which the respective fields SF1, SF2 are demarcated.

These fields SF1, SF2 are exposed at separate times so that the respective fields SF1, SF2 overlap at an overlap region A, thereby projecting an image corresponding to a device pattern 2 on the semiconductor substrate 1. To provide the overlap region A in this manner prevents occurrence of a gap between exposure regions S1, S2 respectively corresponding to the fields SF1, SF2, and also prevents disconnection of the device pattern 2 at the gap. A connecting portion of the device pattern 2 formed by connecting the fields SF1, SF2 in the dividing exposure is referred to as a connecting line herein.

When the exposure regions S1, S2 are displaced, the shape of the device pattern 2 is deformed. Even when there is no displacement, the line width of the resist pattern varies at the overlap region A and the shape of the device pattern 2 tends to be deformed as compared with other portions because a photoresist is exposed twice.

FIG. 2 is a plan view of the device pattern 2 deformed in the manner as described above.

In the example, a case that a positive photoresist was exposed is assumed, in which the exposure amount in the overlap region A is overdosed and the line width of the resist pattern becomes narrow, as a result, a narrow width portion 2n shown in the drawing is formed in the device pattern 2.

In the case that the device pattern 2 is wiring, wiring resistance increases when it is deformed in this manner, which causes problems such as defects in a semiconductor device.

Accordingly, in the dividing exposure method, it is necessary to monitor deformation of the device pattern 2 in the overlap region A as well as to judge whether the deformation is significantly large enough to make the semiconductor device defective. When it is judged that the semiconductor device will be defective, the deformation of the device pattern 2 is made to be small by correcting the exposure amount or the like.

However, it is inevitable that the exposure amount in the overlap region A is overdosed as compared with other regions even when corrected as described above, therefore, it is difficult to completely prevent the deformation of the device pattern 2. In addition, the deformation of the device pattern 2 at the connecting portion sometimes occurs also by the displacement generated in the dividing exposure. However, the deformation of the device pattern 2 is not actually found until the completed semiconductor device is judged to be defective in an electrical test.

### SUMMARY

According to one aspect of the present invention, a method of manufacturing a semiconductor device has a first exposure to the photoresist by using a first mask having a first portion of a monitor pattern, a second exposure to the photoresist by using a second mask having a second portion of the monitor pattern so that a first image of the first portion and a second image of the second portion are connected.

### BRIEF DESCRIPTION OF THE DRAWINGS

FIG. 1 is a schematic view showing a dividing exposure method;

FIG. 2 is a plan view of a device pattern deformed due to the dividing exposure;

FIG. 3 is a plan view of an exposure mask used in an embodiment of the invention;

FIGS. 4A and 4B are plan views in which monitor patterns formed separately in a first and second sub-fields are connected;

FIG. 5 is a schematic view showing an exposure method;

FIGS. 6A to 6E are cross-sectional views of manufacturing processes of a semiconductor device;

FIGS. 7A and 7B are plan views of manufacturing processes of the semiconductor device;

FIG. 8 is a plan view showing an inspection method of the semiconductor device;

FIG. 9 is a plan view showing an inspection method of the semiconductor device;

FIGS. 10A to 10D are cross-sectional views of manufacturing processes of a semiconductor device;

FIGS. 11A to 11D are plan views of the manufacturing processes of a semiconductor device;

FIG. 12 is a plan view showing an inspection method of the semiconductor device;

FIG. 13 is a cross-sectional view in the case that another interlayer insulating film is formed over a conductive monitor pattern;

FIGS. 14A to 14D are cross-sectional views for explaining a damascene process; and

FIG. 15 is a plan view of a conductive monitor pattern formed by the damascene process.

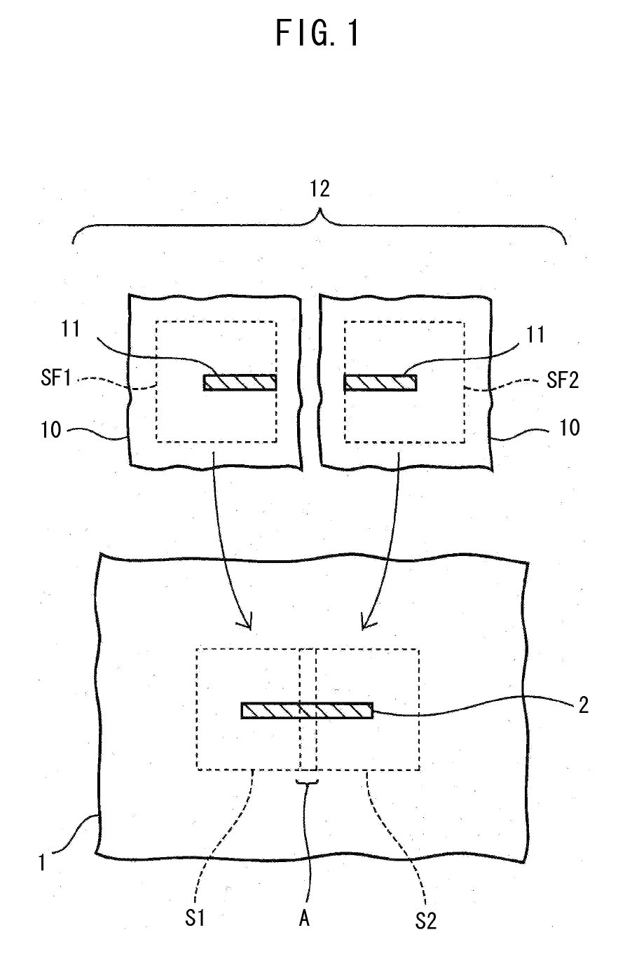

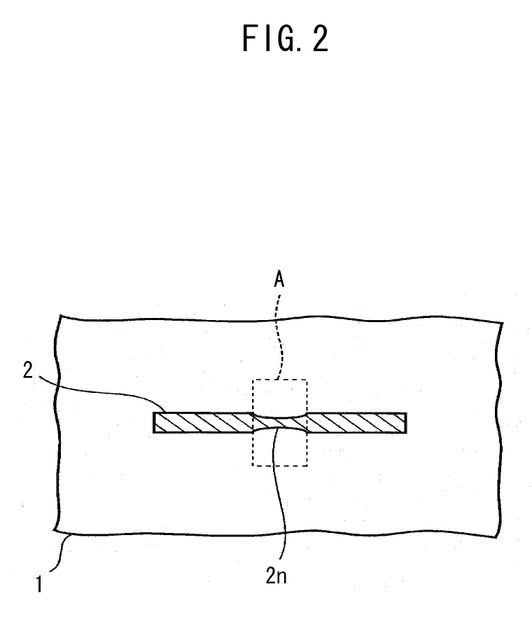

### DESCRIPTION OF THE PREFERRED EMBODIMENTS

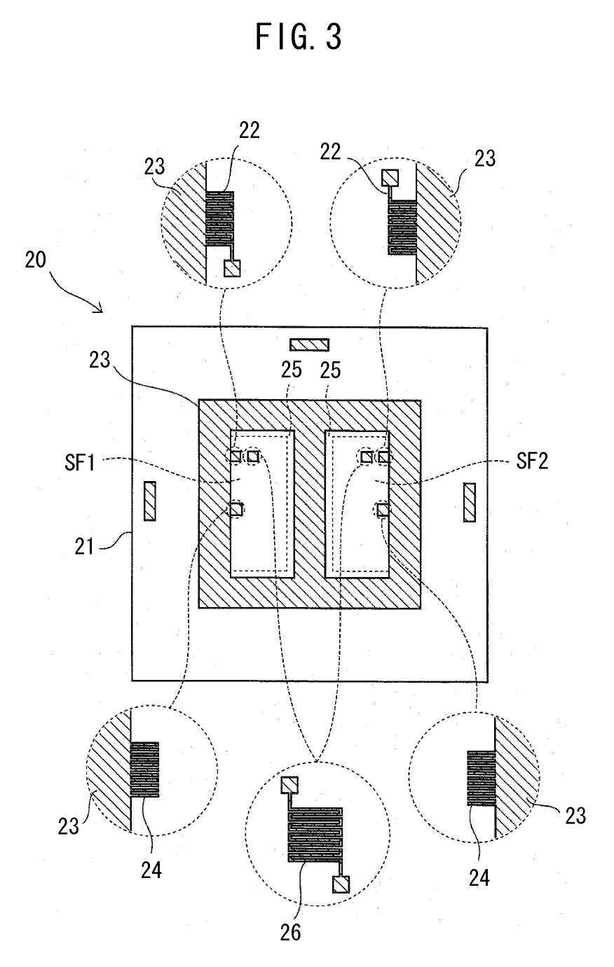

FIG. 3 is a plan view showing a mask for dividing exposure used in the embodiment.

A mask for dividing exposure 20 includes a shielding zone 23 formed of a chrome film or the like over a transparent substrate 21 formed of a quartz material or the like. In first and second sub-fields SF1, SF2 demarcated by openings of the shielding zone 23, monitor patterns 22 and auxiliary monitor patterns 26 formed of a shielding film such as a chrome film and the like are formed.

In respective sub-fields SF1, SF2, actual shielding patterns 24 corresponding to actual patterns such as wiring are formed at portions inside scribing regions 25 so as to be apart from the patterns 22, 26.

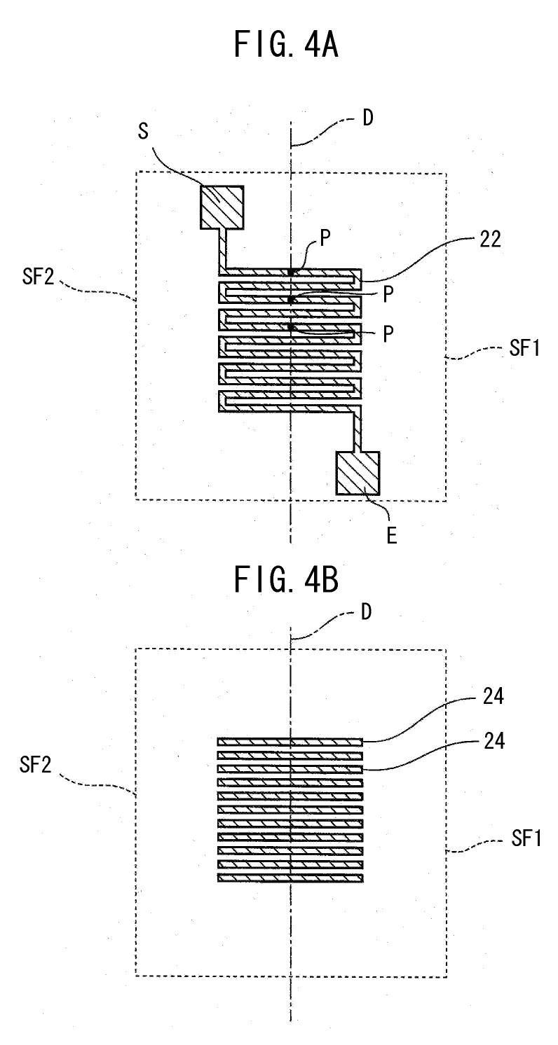

FIG. 4A is a plan view in which the monitor pattern 22 formed separately in the first and second sub-fields SF1, SF2 are connected.

As illustrated in the figure, the monitor pattern 22 has a plane shape of a band extending meanderingly back and forth from a start point S to an end point E. One side of the monitor pattern 22 divided by a dividing line D as a boundary is formed in the first sub-field SF1 and the other side thereof is formed in the second sub-field SF2.

Though a manner of dividing the monitor pattern 22 by the dividing line D is not limited, in the present embodiment, the monitor pattern 22 is divided so that the dividing line D intersects with the monitor pattern 22 at plural points P as shown in FIG. 4A.

On the other hand, FIG. 4B is a plan view in which the actual patterns 24 formed separately in the first and second sub-fields SF1, SF2 are connected. In the example, the actual shielding pattern 24 has a plane shape of a band corresponding to wiring.

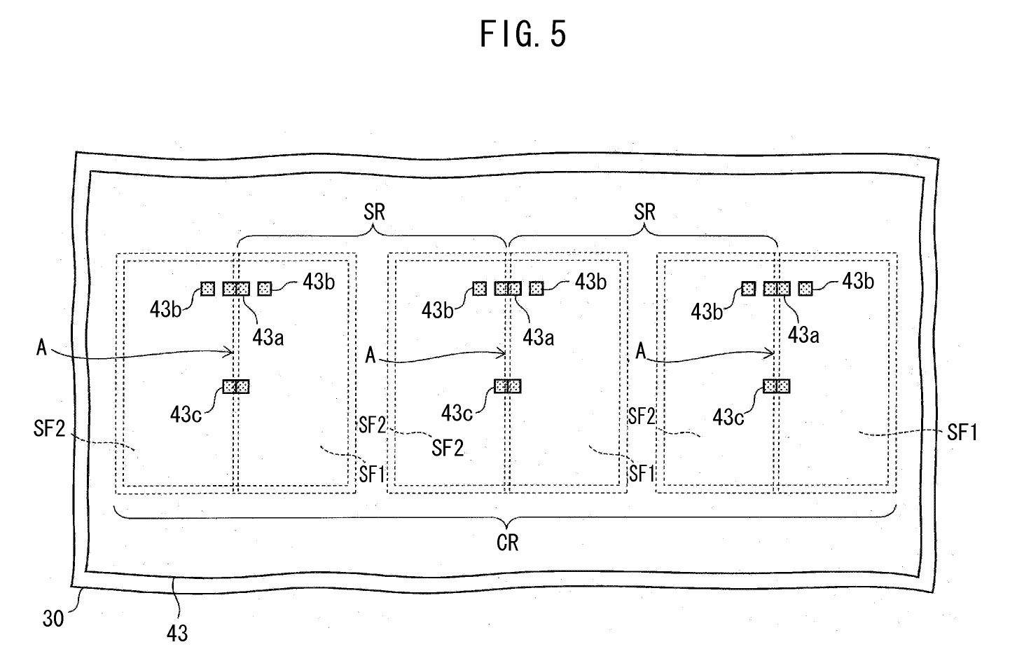

FIG. 5 is a schematic view showing the exposure method according to the embodiment.

In the embodiment, the mask for dividing exposure 20 is set in an aligner such as a stepper, dividing exposure is performed to a photoresist 43 so that images of the monitor patterns 22 formed separately in the first and second sub-fields SF1, SF2 are connected, shifting an exposure region SR. At this time, the exposure is performed while parts of adjacent exposure regions SR are made to overlap each other at overlap regions A in order to prevent disconnection of the device pattern between adjacent exposure regions SR.

According to such dividing exposure, first latent images 43a corresponding to the monitor patterns 22 connected at the overlap regions A are formed in the photoresist 43 of one chip region CR.

At sides of the first latent images 43a, second latent images 43b corresponding to auxiliary monitor patterns 26 are formed.

At device regions of a silicon substrate 30, third latent images 43c corresponding to the actual shielding patterns 24 connected at the overlap regions A are formed.

In the dividing exposure according to the embodiment, the photoresist 43 in one chip region CR is exposed by performing plural exposures.

Herein, as a method of forming a monitor pattern including a conductive layer, a case in which, after the conductive layer such as aluminum is deposited, a conductive pattern is formed by etching will be explained, however, the method of forming the monitor pattern is not limited thereto. For example, it is preferable to use a method in which a conductive layer such as Cu is formed in a trench in an insulating film by Chemical Mechanical Polishing (CMP).

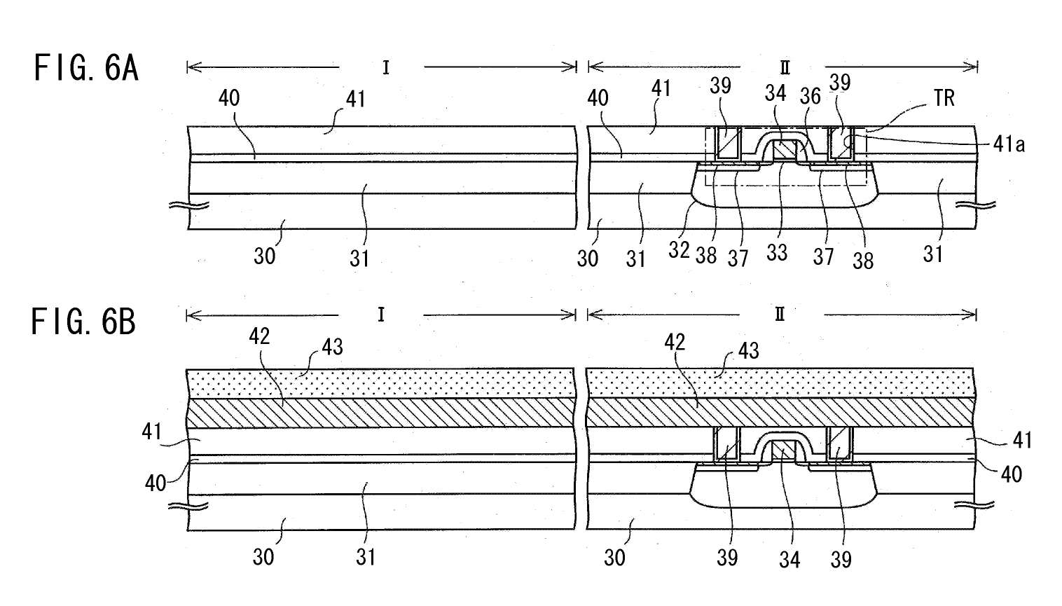

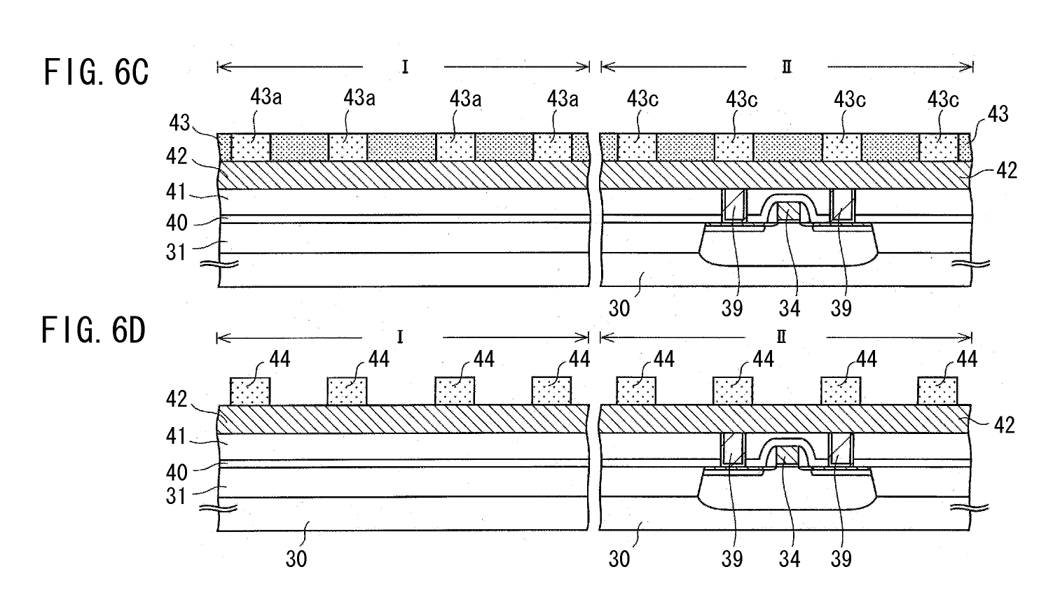

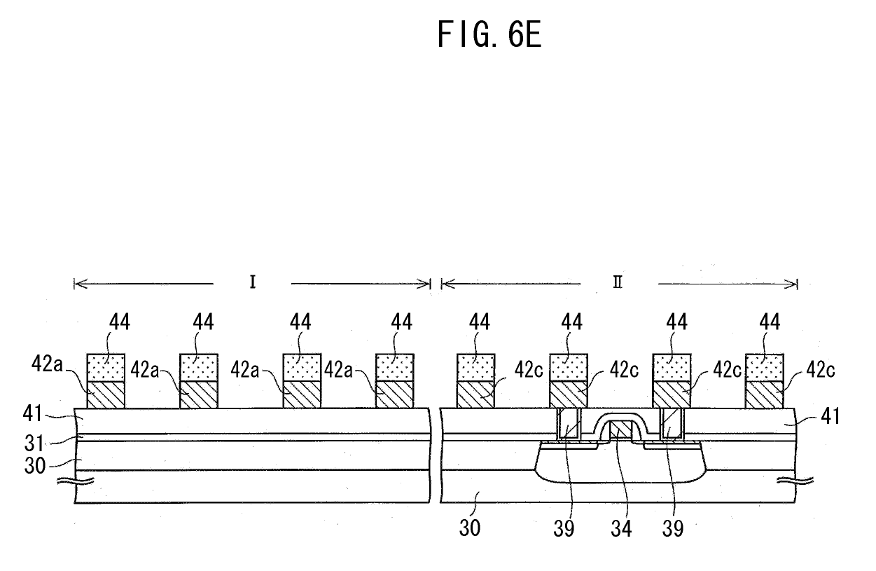

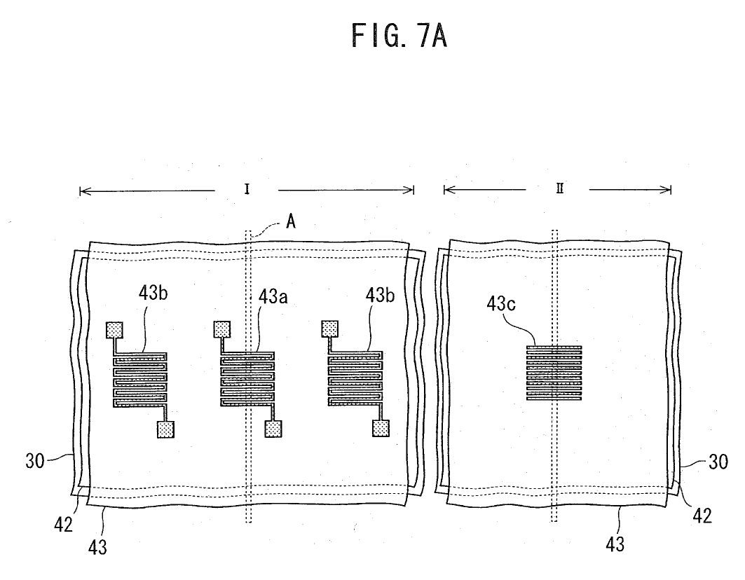

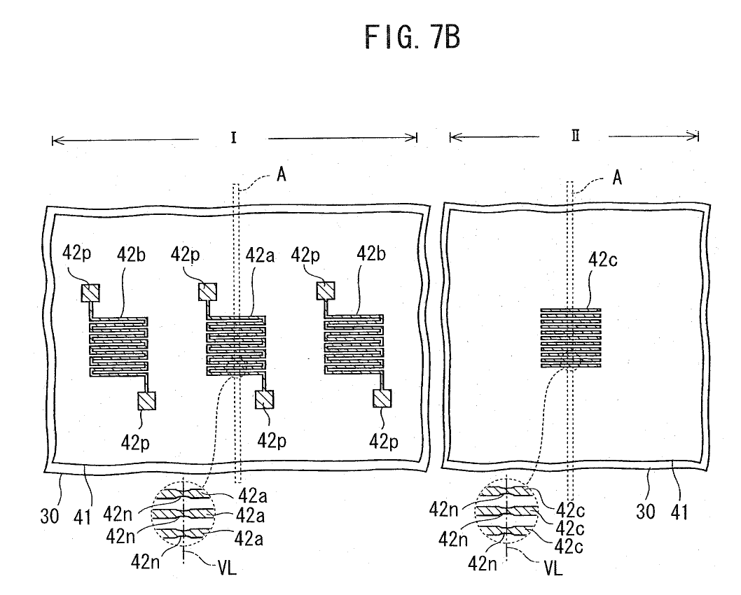

FIGS. 6A to 6E are cross-sectional views of a semiconductor device according to the embodiment during manufacturing and FIGS. 7A and 7B are plan views thereof.

In these drawings, a free region I of the semiconductor device and a device region II in which a circuit is formed are drawn side by side.

An element isolation insulating film 31 is embedded in an element isolation trench formed at a p-type silicon substrate 30 to fabricate a Shallow Trench Isolation (STI). After a p-well 32 is formed in the silicon substrate 30, a gate insulating film 33 and a gate electrode 34 are formed over the silicon substrate 30 in this order.

Then, an insulating film such as a silicon oxide film is formed over the whole upper surface of the silicon substrate 30, and the insulating film is etched back and an insulating side wall 36 remains at the side of a gate electrode 34. After that, source/drain regions 37 are formed by ion-implanting an n-type impurity in the silicon substrate 30 at the side of the gate electrode 34. The source/drain regions 37 are made to be low resistant by a metal silicide film 38 such as a titanium silicide film.

According to the above, a MOS transistor TR including the gate electrode 34, the source/drain regions 37 and the like is formed at the active region of the silicon substrate 30.

A cover insulating film 40 and an interlayer insulating film 41 are formed respectively over the surface of the silicon substrate 30 by a Chemical Vapor Deposition (CVD) method. The cover insulating film 40 is formed of, for example, a silicon nitride film having a thickness of approximately 200 nm, and the interlayer insulating film 41 is formed, for example, of a silicon oxide film having a thickness of approximately 800 nm.

Then, after contact holes 41a are formed by patterning these insulating films 40, 41, conductive plugs 39 formed of, for example, tungsten are formed in the contact holes 41a.

As shown in FIG. 6B, a metal stacked film is formed as a conductive film 42 by a sputtering method over the interlayer insulating film 41 and the conductive plugs 39 respectively. The metal stacked film is made by forming a titanium nitride film of, for example, 150 nm, an aluminum film including copper of, for example, 550 nm, a titanium film of, for example, 5 nm and a titanium nitride film of, for example, 150 nm in this order.

After that, the positive photoresist 43 is coated over the conductive film 42.

As shown in FIG. 6C, the dividing exposure is performed with respect to the photoresist 43 by using the above described mask for dividing exposure 20. A method for the dividing exposure is omitted here because it is the same as the one explained in FIG. 5.

FIG. 7A is a plan view after the dividing exposure is completed. As shown in the drawing, the first latent image 43a having the shape corresponding to the monitor pattern 22 and the second latent images 43b corresponding to the auxiliary monitor patterns 26 are formed at the free region I of the photoresist 43 according to the dividing exposure.

On the other hand, at the device region II of the photoresist 43, the third latent image 43c corresponding to the actual shielding pattern 24 is formed.

As shown in FIG. 6D, the photoresist 43 is removed except the first to third latent images 43a to 43c by developing the photoresist 43 to form a resist pattern 44 including these latent images.

As shown in FIG. 6E, the conductive film 42 is dry-etched, using the resist pattern 44 as a mask. After that, the resist pattern 44 is removed.

FIG. 7B is a plan view after the process is completed. As illustrated therein, wiring 42c corresponding to the actual shielding pattern 24 is formed in the device region II. The wiring 42c forms a circuit in the device region II with the MOS transistor TR.

Since the actual shielding pattern 24 is formed in the first and second sub-fields SF1 and SF2 which are bounded by the dividing line D as shown in FIG. 4B, the wiring 42c corresponding to the actual shielding pattern 24 is also formed so as to straddle both a region corresponding to the first sub-field SF1 and a region corresponding to the second sub-field SF2 over the interlayer insulating film 41.

On the other hand, a conductive monitor pattern 42a and auxiliary conductive monitor patterns 42b are formed so as to correspond to the monitor pattern 22 and the auxiliary monitor patterns 26 of the mask for dividing exposure 20 respectively in the free region I. These monitor patterns 42a, 42b are independent from the circuit of the device region II and will be floating potentials in the completed semiconductor device.

The auxiliary conductive monitor patterns 42b are formed so as to belong to a region corresponding to the first sub-field SF1 and a region corresponding to the second sub-field SF2 so as not to straddle the overlap region A, and included the same plane layout as the monitor pattern 22 in design.

Each of the conductive monitor pattern 42a and the auxiliary monitor patterns 42b are provided with conductive test pads 42p used in a later-described inspection.

The conductive monitor pattern 42a is positioned at a joint of exposures of the divided exposure, therefore, the shape thereof tends to change in the overlap portion A where respective exposures are double-exposed, as a result, narrow width portions 42n are sometimes formed in the overlap portion A as shown in FIG. 7B.

In the embodiment, the monitor pattern 22 is divided, by the dividing line D as a boundary as shown in FIG. 4A, therefore, plural narrow width portions 42n are formed.

According to the same reason, narrow width portions 42n can be formed along the virtual line VL also in the wiring 42c formed in the device region II.

On the other hand, the auxiliary conductive monitor patterns 42b are not positioned at the joint of exposures, and not intersecting with the connecting line VL. Therefore, the narrow width portion as described above is not formed.

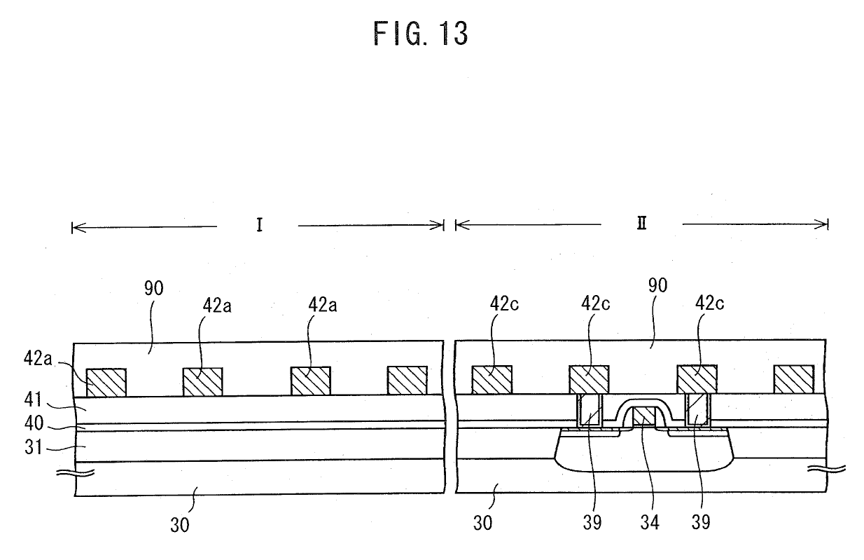

An inspection method of the semiconductor device manufactured as the above will be explained. There are the following two patterns in the inspection method. It is preferable that both methods are performed at an early stage before the semiconductor device is completed, for example, before an another interlayer insulating film 90 is formed over the conductive monitor pattern 42a as shown in FIG. 13.

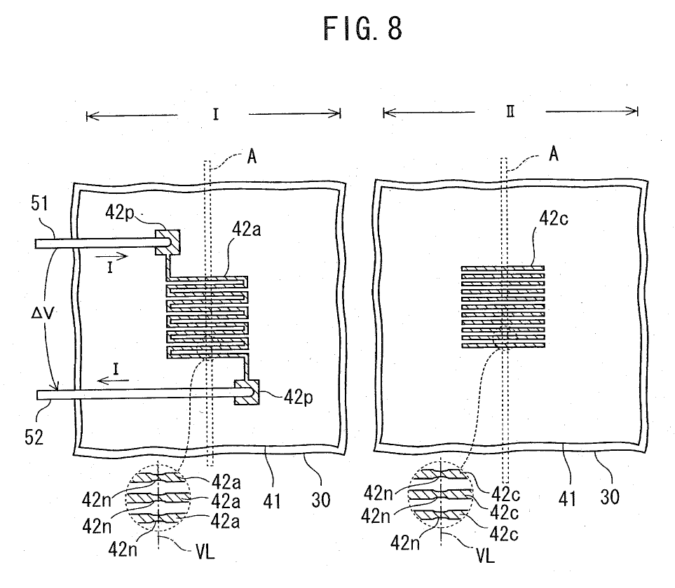

FIG. 8 is a plan view showing an inspection. The inspection is performed by using only the conductive monitor pattern 42a, and the auxiliary conductive monitor pattern 42b is not used.

In the inspection, probes 51, 52 are allowed to abut on the conductive test pads 42p. A test current I is allowed to flow between these probes 51, 52 to measure a voltage falling ΔV in the conductive monitor pattern 42a. Then, a resistance value R of the conductive monitor pattern 42a is calculated from the test current I and the voltage falling ΔV.

When the resistance value R is greater than a reference value R0 which was previously determined, it can be estimated that the narrow width portion 42n of the conductive monitor pattern 42a is narrower than the allowable range as well as a resistance value R of the wiring 42c at the overlap portion A is also higher than the allowable range in design.

When the resistance value R is greater than the reference value R0, it is judged that the semiconductor device will be defective.

On the other hand, when the resistance value R is equal to or less than the reference value R0, it is judged that a defect caused by the deformation of the wiring 42c in the overlap portion A will not occur.

For example, in the case that the line width of the conductive monitor pattern 42a is 0.35 μm, when respective potentials of the probes 51, 52 are 3 V and 2.9 V, the voltage falling ΔV is 0.1 V and the resistance value R is approximately several Ω, it is judged that a defect will not occur.

The above inspection can be performed in the wafer level when the conductive monitor pattern 42a is formed. Therefore, it is possible to easily find whether there are defects caused by the dividing exposure or not at an early stage of the manufacturing process without waiting for the electrical test performed to the semiconductor devices just before the shipping as products.

Moreover, in the embodiment, the conductive monitor pattern 42a intersects with the virtual line VL at plural points by allowing the conductive monitor pattern 42a to meander back and forth, therefore, plural narrow width portions 42n can be formed in the conductive monitor pattern 42a. Accordingly, it is possible that the degree of deformation of the conductive monitor pattern 42a in the narrow width portions 42n is allowed to reflect on the resistance value R at high sensitivity, as a result, the accuracy for judging whether the semiconductor device will be defective or not is high.

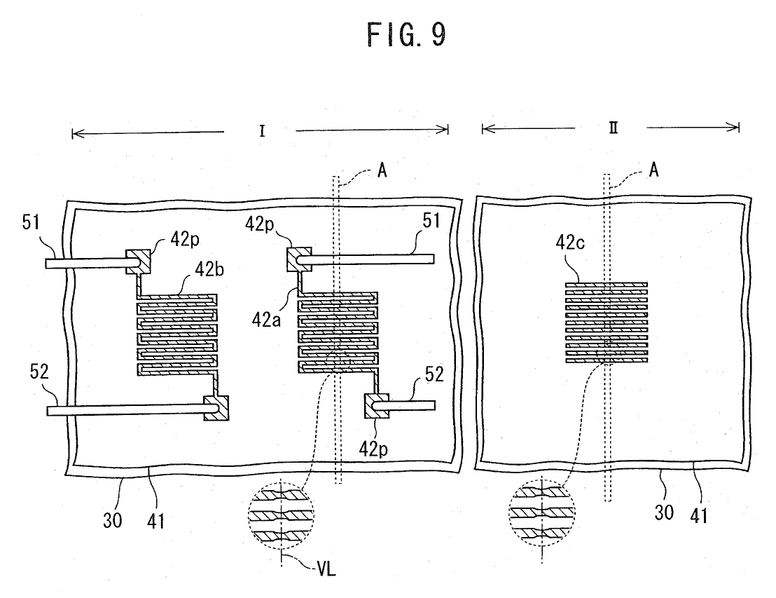

FIG. 9 is a plan view showing another inspection method. The inspection is performed by using both the conductive monitor pattern 42a and the auxiliary conductive monitor pattern 42b.

In the inspection, a resistance value R1 of the conductive monitor pattern 42a and a resistance value R2 of the auxiliary conductive monitor pattern 42b are calculated by using the probes 51, 52.

The narrow width portion is not formed in the auxiliary conductive monitor pattern 42b, therefore, the resistance value R2 of the auxiliary conductive monitor pattern 42b can be used as a reference resistance value in the case that there is no narrow width portion.

The resistance value R2 is used as the reference value. In the case that the difference R1-R2 when comparing the resistance value R1 with the value R2 is greater than an allowable value ΔR, it is judged that the semiconductor device will be defective because of the deformation of the wiring 42c in the overlap portion A.

On the other hand, in the case that the difference R1-R2 is equal to or less than the allowable value ΔR, it is judged that the semiconductor device will not be defective.

Also in the example, the inspection can be performed in the wafer level at the time of forming respective conductive monitor patterns 42a, 42b, therefore, it is possible to find defects occurring by the dividing exposure at the early stage.

In the above embodiment, the resistance of the conductive monitor pattern 42a is measured to find defects of the semiconductor device, however, the invention is not limited to this, and it is also preferable to measure the resistance calculated by adding a conductive pattern stacked as described below and a conductive plug.

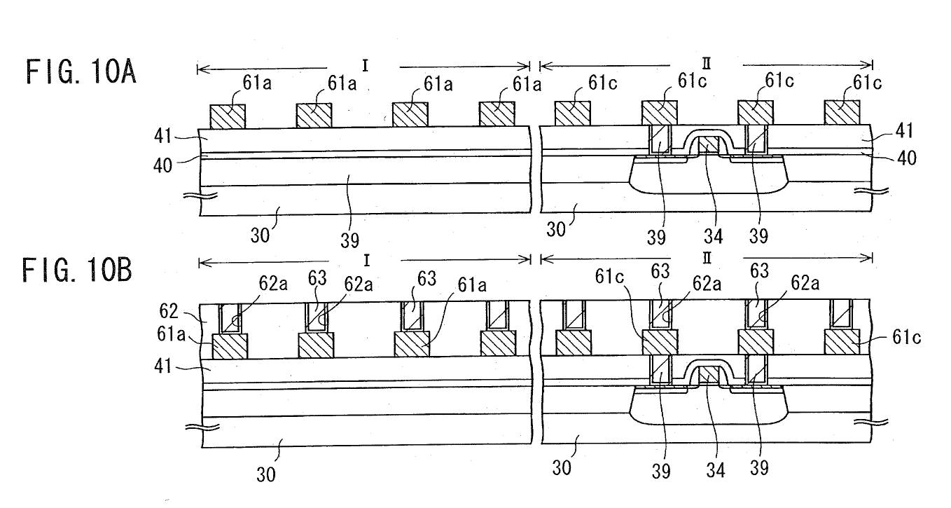

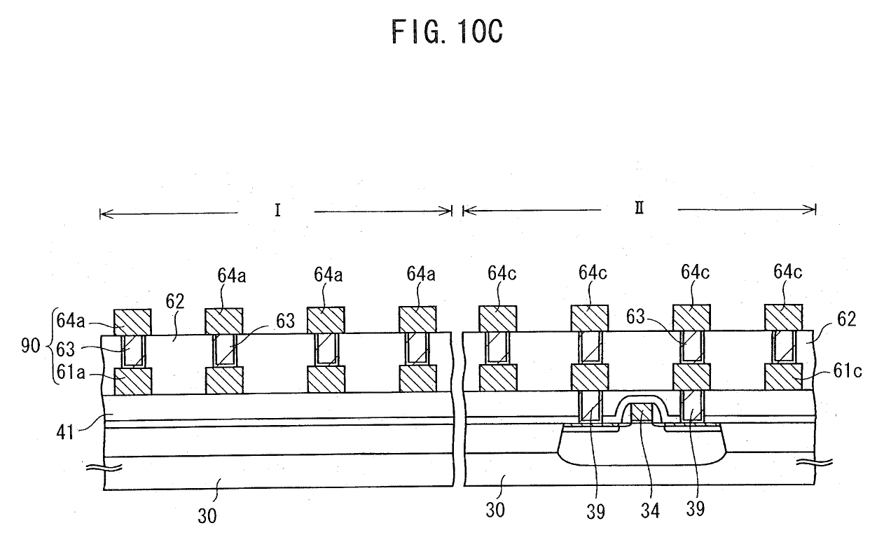

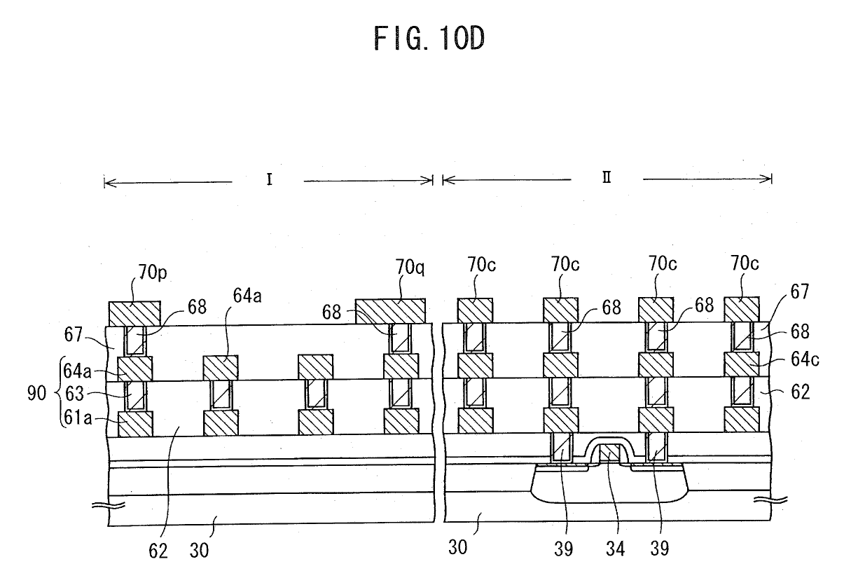

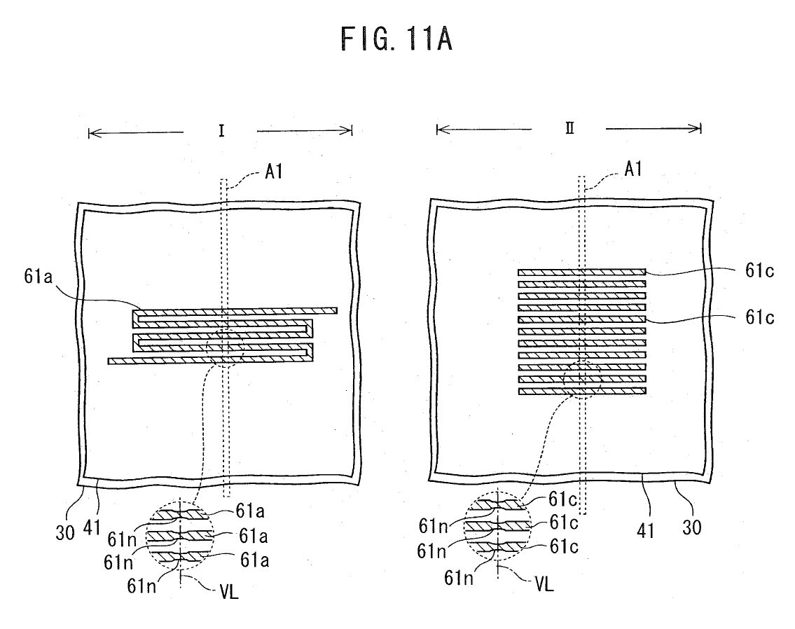

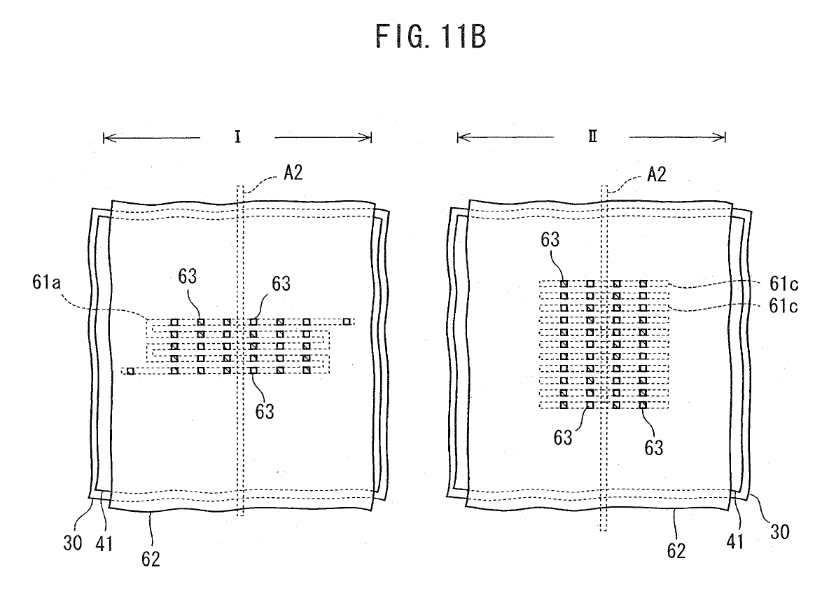

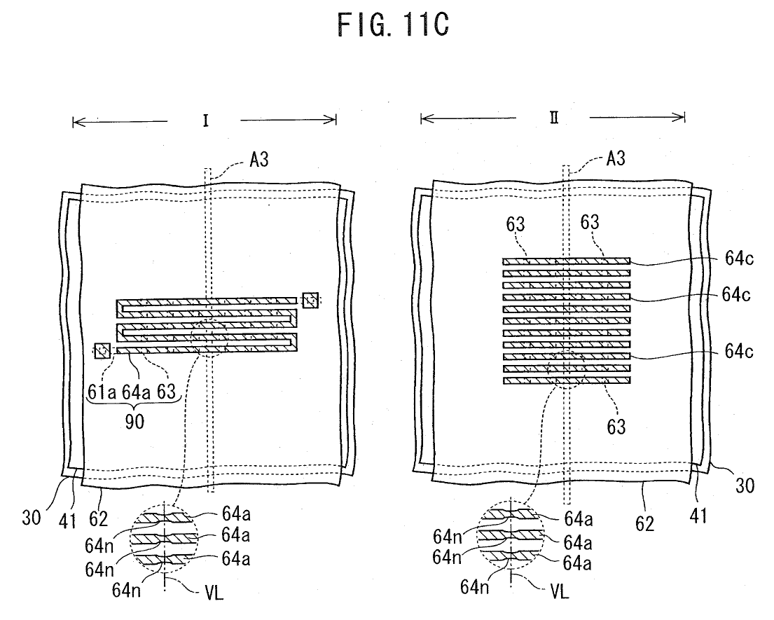

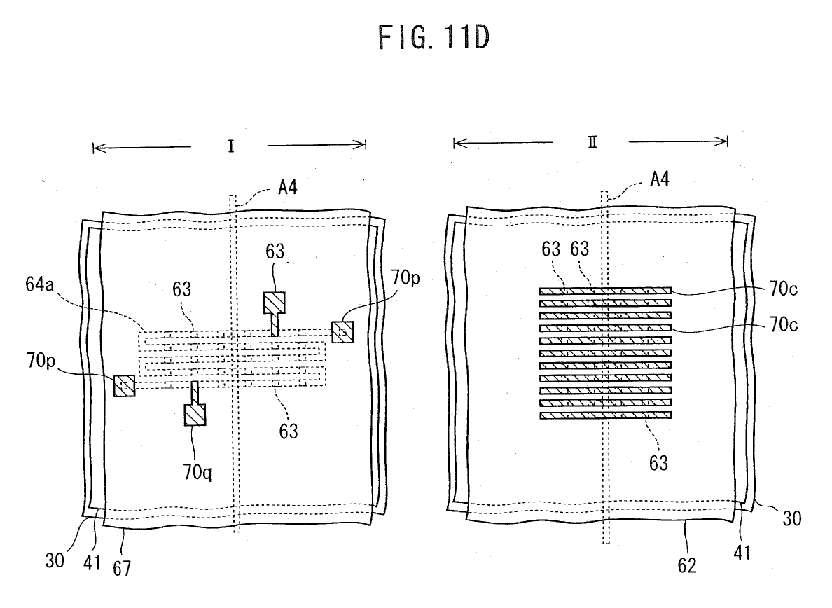

FIGS. 10A to 10D are cross-sectional views of a semiconductor device during manufacture, and FIG. 11A to 11D are plan views thereof.

In order to form the semiconductor device, the interlayer insulating film 41 is formed over the silicon substrate 30 as shown in FIG. 10A by following the already-described process of FIG. 6A.

Then, a lower conductive pattern 61a and lower wiring 61c are formed over the interlayer insulating film 41 in the free region I and the device region II respectively by patterning using the dividing exposure, following the same process of the forming process of the conductive monitor pattern 42a and the wiring 42c explained in FIG. 6B to 6E.

FIG. 11A is a plan view after the process is completed. The narrow width portions 61n caused by overdose due to double exposure are sometimes formed in the lower conductive pattern 61a and the lower wiring 61c in an overlap region A1 of the dividing exposure.

The process until obtaining a cross-sectional structure shown in FIG. 10B will be explained.

For example, a silicon oxide film is formed as an interlayer insulating film 62 by the CVD method over the lower conductive pattern 61a and the lower wiring 61c, respectively. Next, the interlayer insulating film 62 is patterned by photolithography using the dividing exposure and etching to form holes 62a on the lower conductive pattern 61a and the lower wiring 61c respectively.

Then, for example, a titanium nitride film is formed as a glue film inside the holes 62a and over the interlayer insulating film 62 respectively by the sputtering method, then, for example, a tungsten film is formed over the glue film by the CVD method to bury the holes 62a by the tungsten film. After that, excessive glue film and the tungsten film over the interlayer insulating film 62 are removed by polishing by the CMP method to allow these films as conductive plugs 63 inside the holes 62a.

FIG. 11B is a plan view after the process is completed. Though the holes 62a are formed by the dividing exposure, the holes 62a are not positioned on an overlap region A2 of the dividing exposure, therefore, deformation caused by overdose and the like does not occur in the holes 62a.

As shown in FIG. 10C, in the same manner as the lower conductive pattern 61a and the lower wiring 61c, an upper conductive pattern 64a and upper wiring 64c are formed over the interlayer insulating film 62 in the free region I and the device region II respectively by patterning using the dividing exposure, following the processes of FIGS. 6B to 6E.

A stacked body of the lower conductive pattern 61a, the conductive plug 63 and the upper conductive pattern 64a formed in the free region I as described above will be a conductive monitor pattern 90 to be an inspection target.

Both of the lower conductive pattern 61a and the upper conductive pattern 64a are formed by patterning using the dividing exposure, however, it is also preferable that dividing exposure is applied to only either of them.

FIG. 11C is a plan view after the process is completed. As shown in FIG. 11C, in an overlap region A3 of the dividing exposure of the present process, the upper conductive pattern 64a and the upper wiring 64c are deformed by overdose and the like, and narrow width portions 64n sometimes result therein.

As shown in FIG. 10D, an interlayer insulating film 67 and conductive plugs 68 are formed over the upper conductive pattern 64a and the upper wiring 64c respectively by using the same method as the forming method of the already-described interlayer insulating film 62 and the conductive plugs 63 as shown in FIG. 10D.

Furthermore, a metal stacked film is formed over the interlayer insulating film 67 and the conductive plugs 68 respectively by the sputtering method, and the metal stacked film is patterned to form first and second conductive test pads 70p, 70q in the free region I as well as to form final wiring 70c in the device region II.

FIG. 11D is a plan view of the semiconductor device. As shown in FIG. 11D, two sets of the first and second conductive test pads 70p, 70q are formed in the free region I.

Patterning using the dividing exposure is performed in all processes of the forming process of the conductive pattern 61a and the wiring 61c, the forming process of the holes 62a, and the forming process of the conductive pattern 64a and the wiring 64c and the first and second conductive test pads 70p, 70q and the wiring 70c. In each patterning, the dividing exposure is performed so that respective overlap regions A1 to A4 correspond.

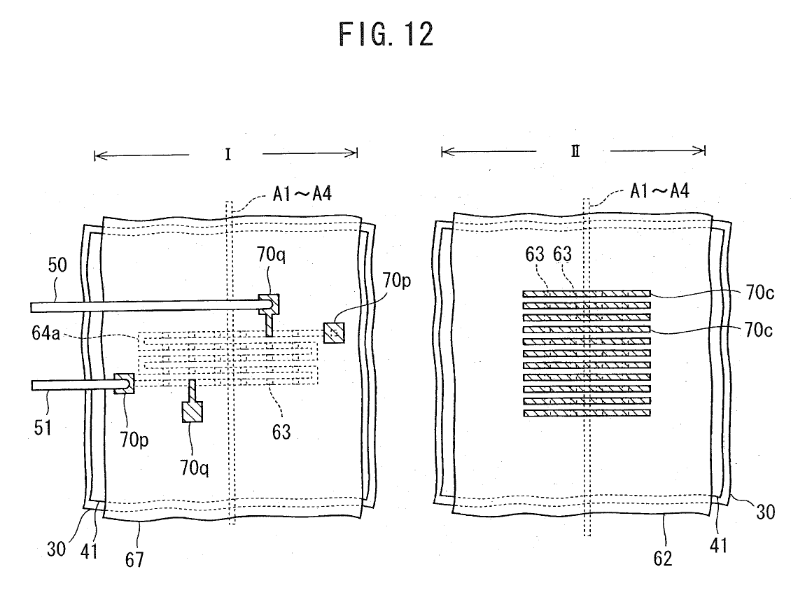

FIG. 12 is a plan view showing an inspection method of the semiconductor device.

In the inspection, the probe 51 is allowed to contact to one of the two first conductive test pads 70p and the probe 52 is allowed to contact to one of the second conductive test pads 70q as shown in the drawing, and a test current is allowed to flow between these probes 51, 52.

The test current I flows in the conductive pattern 61a, the conductive plug 63, and the conductive pattern 64a forming the conductive monitor pattern 90 in order, and voltage falling ΔV caused by the test current I flowing in these elements is generated between the probes 51, 52.

A resistance value R in which all the conductive pattern 61a, the conductive plug 63 and the conductive pattern 64a are added is calculated based on the voltage falling ΔV and the test current I.

The resistance value R includes contact resistance of the conductive plug 63 in addition to the resistance caused by the respective narrow width portions 61n, 64n of the conductive pattern 61a and the conductive pattern 64a.

When the resistance value R is greater than the reference value R0, defects caused by high contact resistance of the conductive plug 63 can be found in the early stage in addition to defects caused by the narrow width portions 61n, 64n.

When the resistance value R is equal to or less than the reference value R0, it can be judged that the semiconductor device will not be defective due to the narrow width portions 61n, 64n and the contact resistance. In addition, it can be confirmed that the displacement which affects electric properties of the device placed at the connecting position does not occur.

The embodiment of the invention has been explained in detail as the above, however, the invention is not limited to the above embodiment. For example, the conductive monitor pattern 42a is formed in the same layer as the wiring 42c in the above embodiment, however, instead of that, it is also preferable that a conductive monitor pattern is formed in the same layer as the gate electrode 34 to find defects of the gate electrode 34 caused by the dividing exposure.

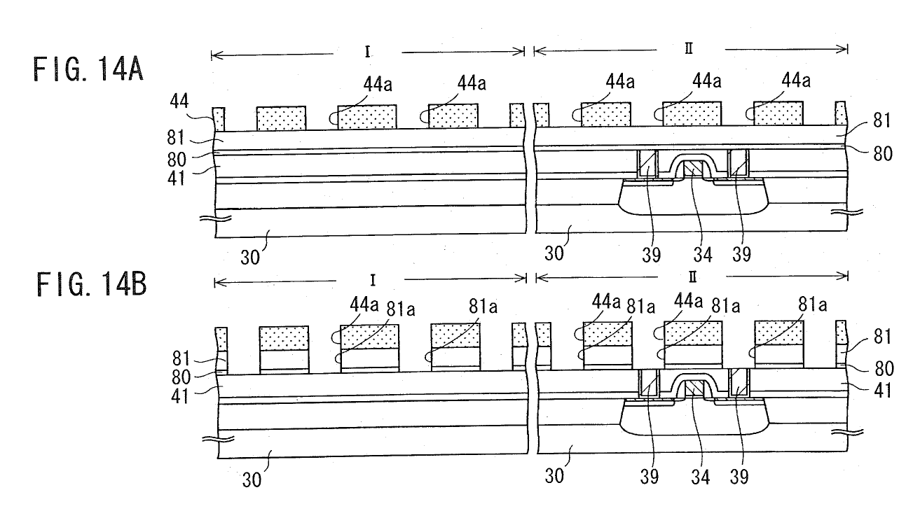

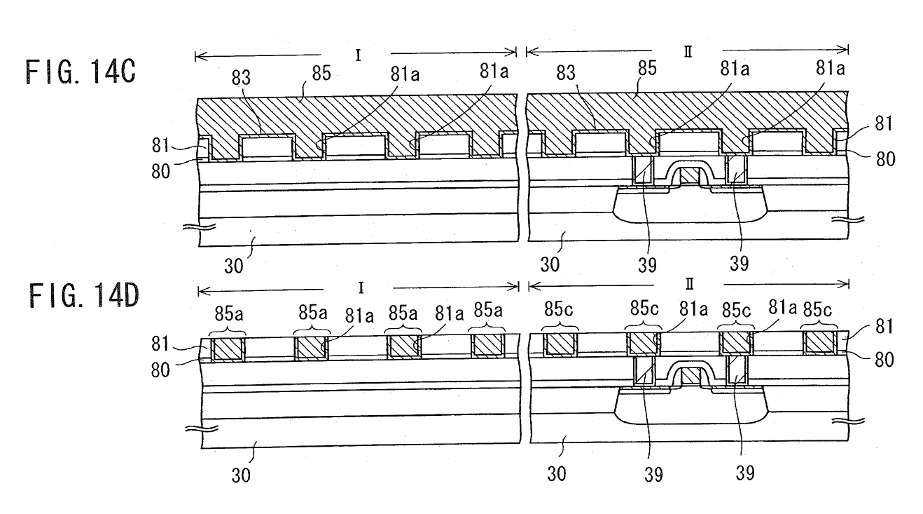

The invention can be also applied to a damascene process in which a wiring trench is formed in an insulating film and wiring materials such as copper are buried in the wiring trench to form wiring. The damascene process will be explained with reference to FIGS. 14A to 14D as follows.

After the already-described process of FIG. 6A is performed, a silicon nitride film is formed as an etching stopper film 80 over the interlayer insulating film 41 and the conductive plugs 39 respectively as shown in FIG. 14A by the CVD method.

Furthermore, a silicon oxide film is formed over the etching stopper film 80 by the CVD method as an insulating film 81 in which wiring is buried in the later process.

Then, a resist pattern 44 is formed over the insulating film 81 by following the processes explained in FIGS. 6B and 6C.

As shown in FIG. 14B, the etching stopper film 80 and the insulating film 81 are etched, using the resist pattern 44 as a mask to form a trench 81a in these films under windows of the resist pattern 44.

The etching is performed, for example, in two steps. In the first step, the insulating film 81 is selectively etched so that etching is stopped on the surface of the etching stopper film 80. Then, in the second step, the etching stopper film 80 is etched.

After that, the resist pattern 44 is removed. As shown in FIG. 14C, a tantalum nitride film is formed as a barrier metal film 83 by the sputtering method over the upper surface of the trench 81a and the insulating film 81.

Furthermore, a copper film is formed as a conductive film 85 over the barrier metal film 83 by electrolytic plating, and the trench 81a is completely buried by the conductive film 85.

After that, as shown in FIG. 14D, excessive barrier metal film 83 and the conductive film 85 over the insulating film 81 are polished by the CMP method. Accordingly, a conductive monitor pattern 85a corresponding to the monitor pattern 22 is formed in the trench 81a in the free region I as well as wiring 85c is formed in the trench 81a in the device region II.

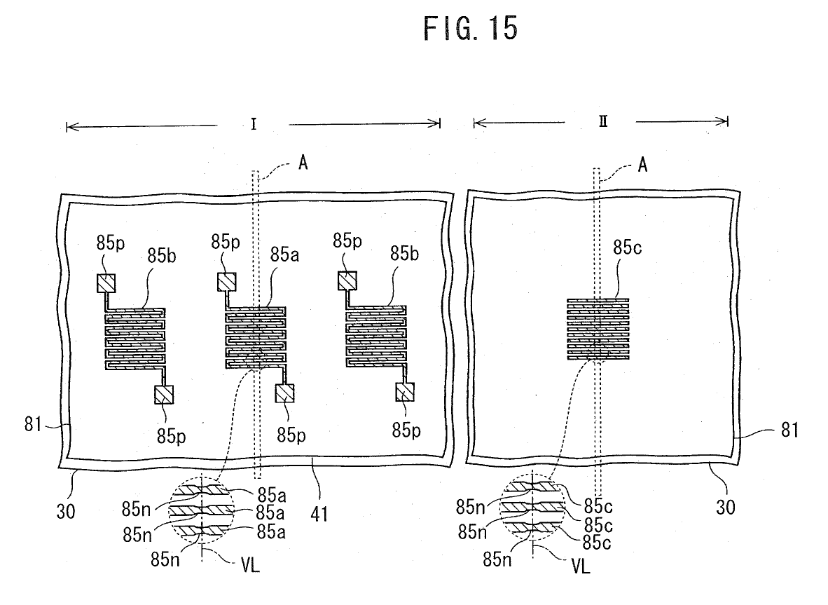

FIG. 15 is a plan view after the process is completed. As shown in FIG. 15, auxiliary conductive monitor patterns 85b are also formed by the same forming method as the conductive monitor pattern 85a in the free region I. Then, conductive test pads 85p used in the inspection are formed. The conductive test pads 85p connect to conductive monitor patterns 85a, 85b.

Also according to the conductive monitor patterns 85a, 85b formed by the above damascene method, it can be judged that the semiconductor device to be completed will be defective or not by performing inspection by following the inspection method described in FIG. 8 or 9.

In the manufacturing method of the semiconductor device according to the embodiment, the conductive monitor pattern corresponding to the monitor pattern is formed by using an exposure mask in which monitor patterns are formed separately in the first sub-field and the second sub-field. The plane shape of the conductive monitor pattern is sometimes deformed by overdose and the like in the overlap region in which respective shots overlap at the time of dividing exposure in the same way as the device pattern such as wiring.

The degree of deformation of the conductive monitor pattern is reflected on electric properties of the conductive monitor formed at the connecting region, for example, the resistance value thereof, therefore, it is possible to judge whether the semiconductor device will be defective or not due to excessive deformation of the device pattern based on the resistance value of the conductive monitor pattern.

Such judgment can be performed by measuring the resistance value of the conductive monitor pattern before the semiconductor device is completed, therefore, it is possible to find defects of the semiconductor device at an early stage of the manufacturing process.

In addition, it is preferable to apply the monitor pattern which has a plane shape of a band extending meanderingly back and forth, and one side of the monitor pattern divided by a dividing line D as a boundary is formed in the first sub-field and the other side thereof is formed in the second sub-field.

In such a case, plural deformed portions such as narrow width portions can be formed in the conductive monitor pattern by allowing the monitor pattern to intersect with the dividing line at plural points. Accordingly, the degree of deformation of the conductive monitor pattern can be reflected on the resistance value at high sensitively, which increases the judgment accuracy of whether the semiconductor device will be defective or not.

It is also preferable that the conductive pattern, the conductive plug, and the conductive pattern are formed in this order and the stacked body is allowed to the conductive monitor pattern. The resistance value of the conductive monitor pattern includes contact resistance of the conductive plug, therefore, defects caused by the high contact resistance of the conductive plug can be found in addition to defects caused by the deformation of the device pattern occurring in the overlap region of the dividing exposure.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method of manufacturing a semiconductor device, comprising:
forming a first film over a semiconductor substrate;
coating a photoresist over the first film;
performing a first exposure to the photoresist by using a first mask having a first portion of a monitor pattern;
performing a second exposure to the photoresist by using a second mask having a second portion of the monitor pattern so that a first image of the first portion and a second image of the second portion are connected;
forming a resist pattern by developing the photoresist; and
etching the first film by using the resist pattern as a mask.

2. The method of claim 1,
wherein the first film is an insulating film; and
in etching the first film, a trench is formed in the first film, and a conductive monitor pattern corresponding to the monitor pattern is formed by burying a conductive film in the trench.

3. The method of claim 1,
wherein the first film is a conductive film; and
in etching, a conductive monitor pattern corresponding to the monitor pattern is formed by patterning the first film.

4. The method of claim 2,
wherein the conductive monitor pattern is a band-shaped pattern.

5. The method of claim 1,
wherein the first exposure and the second exposure are performed so that a first part of the first portion and a second part of the second portion overlap with each other.

6. The method of claim 1,
wherein the monitor pattern has a plane shape of a band meandering back and forth across the connection between the first and second portions.

7. The method of claim 2,
wherein, in forming the conductive monitor pattern, a conductive pattern forming a circuit is formed so as to straddle both a first region corresponding to the first mask and a second region corresponding to the second mask.

8. The method of claim 1,
wherein the first mask or the second mask further comprises an auxiliary conductive pattern having the same plane layout as the conductive monitor pattern.

9. The method of claim 1,
wherein the conductive monitor pattern includes a lower conductive pattern, a conductive plug and an upper conductive pattern, and
at least one of the lower conductive pattern and the upper conductive pattern is formed so as to straddle the first region and the second region.

10. The method of claim 1, further comprising:
measuring a resistance value of the conductive monitor pattern; and
forming an insulating film over the conductive monitor pattern.

11. A semiconductor device formed by using a dividing exposure method, comprising:
a conductive monitor pattern formed so as to straddle a connecting line in dividing exposure.

12. The semiconductor device according to claim 11,
wherein the conductive monitor pattern includes a band-shaped pattern.

13. The semiconductor device according to claim 12,
wherein the conductive monitor pattern has a plane shape extending back and forth and intersecting with the connecting line at plural points.

14. The semiconductor device according to claim 13, further comprising:
conductive test pads connecting to the conductive monitor pattern.

15. The semiconductor device according to claim 11,
wherein the conductive monitor pattern is formed in a free region of the semiconductor substrate, which is independent from a circuit formed in a device region of the semiconductor substrate.

16. The semiconductor device according to claim 11,
wherein the conductive monitor pattern includes a lower conductive pattern, a conductive plug and an upper conductive pattern.

17. The semiconductor device according to claim 11, further comprising:
an auxiliary conductive monitor pattern having an identical plane layout to the conductive monitor pattern, not intersecting with the connecting line.

18. A mask for dividing exposure comprising:
a substrate having a first sub-field and a second sub-field; and
a monitor pattern bounded by a dividing line, and formed separately in the first sub-field and the second sub-field.

19. The mask for dividing exposure according to claim 18,
wherein the monitor pattern has a plane shape of a band meandering back and forth across the dividing line.

20. The mask for dividing exposure according to claim 19,
wherein the dividing line intersects with the monitor pattern at plural points.
